(19) United States
(12) Patent Application Publication
(10) Pub. No.: US 2015/0063955 A1
(43) Pub. Date: Mar. 5, 2015

(54) LOAD PORT DEVICE AND SUBSTRATE PROCESSING APPARATUS

(71) Applicant: Tokyo Electron Limited, Tokyo (JP)

(72) Inventor: Takahiro MIKI, Yamanashi (JP)

(21) Appl. No.: 14/477,819

(22) Filed: Sep. 4, 2014

(30) Foreign Application Priority Data
Sep. 4, 2013 (JP) 2013-183060

(51) Int. Cl. H01L 21/677

(52) U.S. Cl. CPC H01L 21/67772
USPC 414/217

(57) ABSTRACT

A load port device transfers a semiconductor wafer between a substrate processing apparatus and a container accommodating the semiconductor wafer. The load port device includes: a door for opening and closing the opening from the inside of the substrate processing apparatus, and attaching and detaching a lid of the container to and from the container while holding the lid; a door driving unit for driving the door to open and close the opening; and an elastic body disposed at a surface of the door to correct inclination of the door with respect to an opening surface of the container when the lid held by the door is attached to the container and receives a reactive force from the semiconductor wafer in the container.

### CROSS-REFERENCE TO RELATED APPLICATION

This application claims priority to Japanese Patent Application No. 2013-183060 filed on Sep. 4, 2013, the entire contents of which are incorporated herein by reference.

### FIELD OF THE INVENTION

The present invention relates to a load port device for transferring a substrate between a container accommodating therein substrates and a substrate processing apparatus for performing a process on a substrate, and the substrate processing apparatus having the load port device.

### BACKGROUND OF THE INVENTION

As for a substrate processing apparatus for performing a process on a semiconductor wafer, there is known an apparatus including a load port for mounting thereon a container (pod) accommodating therein a predetermined number of semiconductor wafers. In such a substrate processing apparatus, a semiconductor wafer in the container is unloaded by a wafer transfer robot provided in a loader module positioned adjacent to the load port and is transferred to a substrate processing module for processing the semiconductor wafer. Then, the semiconductor wafer in the substrate processing module is returned to the container mounted on the load port by the same wafer transfer robot.

In general, the container is mounted on the load port to face the loader module in a state where a lid is attached to an opening through which the semiconductor wafer is loaded and unloaded. An opening and a door for opening/closing the opening are provided at a portion of a wall (box-shaped wall forming an external appearance of the loader module) of the loader module, the portion facing the load port and corresponding to the position of the lid of the container. When the door retreats into the loader module while holding the lid of the container mounted on the load port, the inside of the container and the inside of the loader module communicate with each other. Accordingly, the semiconductor wafer can be loaded into and unloaded from the container by the wafer transfer robot.

Here, the door of the loader module has a structure according to a FIMS (Front-opening Interface Mechanical Standard) that is an interface standard specified by SEMI (Semiconductor Equipment and Materials International) standard E62. For example, Japanese Patent Application Publication No. 2010-153843 (JP2010-153843A) discloses a method for detecting whether a lid is adequately attached to a pod in an operation of closing an opening of the pod with the lid in a FIMS system. Further, Japanese Patent Application Publication No. 2012-054271 (JP2012-054271A) discloses a load port device having a structure which withstands a moment generated when driving a door which has an increased weight due to scaling up of a semiconductor wafer.

Recently, a MAC (Multi Application Carrier) is used as a container accommodating therein semiconductor wafers of Φ450 mm. The MAC has a latch mechanism for fixing the lid to an opening surface of a main unit accommodating therein the semiconductor wafers, and a manipulation mechanism for manipulating the latch mechanism is provided at the door of the loader module. Here, when an operation of closing the door holding the lid (operation of closing the opening of the loader module with the door) is performed to attach the lid to the MAC accommodating therein the semiconductor wafers, a latch error may occur between the main unit of the container and the lid, or a door close error that the opening of the loader module may not be completely blocked by the door occurs.

The reason thereof is as follows. In the door closing operation, the semiconductor wafers are pressed by the lid. At this time, a column holing the door is deformed by reactive force applied from the semiconductor wafers to the lid. This results in inclination of a surface of the door which comes in contact with the lid (hereinafter, referred to as “FIMS surface”). As a consequence, the lid is inclined without being in parallel to the opening surface of the container.

Here, JP2010-153843A suggests a technique for detecting inclination and displacement of the door which are caused by scaling up of a wafer. However, JP2010-153843A does not disclose solution to avoid the latch error or the door close error. JP2012-054271A suggests a structure having stiffness sufficient to deal with scaling up of the door. In that case, however, there occur problems such as scaling up of a driving unit for driving the door, weight increase of the loader module, increase of a foot print, cost increase of the load port device.

15

### SUMMARY OF THE INVENTION

In view of the above, the present invention provides a load port device and a substrate processing apparatus capable of reducing a latch error or a door close error without increasing a foot print or a weight.

In view of the above, the aspect of the present invention provides a load port device for allowing transfer of a semiconductor wafer between an inside of a substrate processing apparatus for processing the semiconductor wafer and an inside of a container for accommodating therein the semiconductor wafer by opening a lid of the container and an opening of the substrate processing apparatus when the container is disposed outside the substrate processing apparatus such that the lid faces the opening

The load port device includes: a door for opening and closing the opening from the inside of the substrate processing apparatus, the door being configured to attach and detach the lid of the container to and from a main body of the container while holding the lid; a door driving unit for driving the door to open and close the opening; and an elastic body disposed on a first surface of the door, which is opposite to a second surface in contact with the lid when the lid is held by the door, the elastic body being configured to correct inclination of the second surface of the door with respect to an opening surface of the container to which the lid is to be aligned when the lid held by the door is attached to the main body of the container by the door driving unit and receives a reactive force from the semiconductor wafer accommodated in the container.

The load port device may further includes a column attached to the door driving unit and configured to support the door in a cantilever state through the elastic body and move the door according to said driving of the door driving unit. The elastic body includes at least two leaf springs spaced apart from each other in a lengthwise direction of the column.

The leaf springs may include a first leaf spring disposed at a leading end side of the column and a second leaf spring disposed at the door driving unit side of the column. The first leaf spring has a spring constant greater than a spring constant of the second leaf spring.

The column may include a protrusion at a top surface thereof. An uppermost one of the leaf springs may include a hole formed in a bottom surface thereof. The protrusion of the column is inserted through the hole such that a gap is formed between an outer surface of the protrusion and an inner surface of the hole.

In accordance with another aspect of the present invention, there is provided a substrate processing apparatus including: a substrate processing unit configured to perform a process on a semiconductor wafer; a load port configured to mount thereon a container for accommodating the semiconductor wafer; and a loader module including an opening formed to face the container mounted on the load port, the loader module providing therein a wafer transfer unit for loading and unloading the semiconductor wafer into and from the container through the opening.

The loader module further includes a load port device configured to open a lid of the container and the opening when the container is mounted on the load port.

The load port device includes: a door for opening and closing the opening from the inside of the loader module, the door being configured to attach and detach the lid of the container to and from a main body of the container while holding the lid; a door driving unit for driving the door to open and close the opening; and an elastic body disposed on a first surface of the door which is opposite to a second surface in contact with the lid when the lid is held by the door, the elastic body being configured to correct inclination of the second surface of the door with respect to an opening surface of the container to which the lid is aligned, when the lid held by the door is attached to the main body of the container by the door driving unit and receives a reactive force from the semiconductor wafer accommodated in the container.

In the aspects of present invention, the elastic body for correcting inclination of the door is provided at the door of the load port device. When the lid is attached to the container main body where the semiconductor wafers are accommodated, the reactive force applied from the semiconductor wafers to the lid is absorbed by the elastic body provided at the door. Accordingly, the inclination of the door holding the lid is suppressed. This prevents the occurrence of the latch error between the container main body and the lid and allows the lid to be reliably attached to the container main body. Further, the opening formed in the substrate processing apparatus can be reliably blocked by the door, so that the door close error can be prevented.

### BRIEF DESCRIPTION OF THE DRAWINGS

The objects and features of the present invention will become apparent from the following description of embodiments, given in conjunction with the accompanying drawings, in which:

FIG. 1 is a perspective view showing a schematic configuration of a substrate processing apparatus in accordance with an embodiment of the present invention;

FIG. 2 is a top view showing a schematic configuration of the substrate processing apparatus shown in FIG. 1;

FIGS. 3A and 3B are schematic cross sectional views showing a schematic structure of a load port device of a loader module of the substrate processing apparatus (taken along arrows III-III′ in FIG. 2) and FIG. 3C is a perspective view showing schematic structures of a column and a door of the load port device; and

FIGS. 4A and 4B show a top view and a rear view of a modification of an example in which the door is held by the column forming the load port device.

### DETAILED DESCRIPTION OF THE EMBODIMENTS

Hereinafter, an embodiment of the present invention will be described with reference to the accompanying drawings. In the embodiment of the present invention, a semiconductor wafer (hereinafter, referred to as “wafer”) having a diameter of 450 mm (Φ450 mm) is chosen as a substrate, and a substrate processing apparatus for performing a process on the wafer is used. The process performed on the wafer includes various plasma treatments such as a plasma etching process, a plasma asking process, a plasma CVD film forming process and the like, a coating and developing process such as resist film formation or the like, a cleaning process for removing impurities adhered onto a wafer or the like, a heat treatment for film formation or the like, a wet etching process or the like.

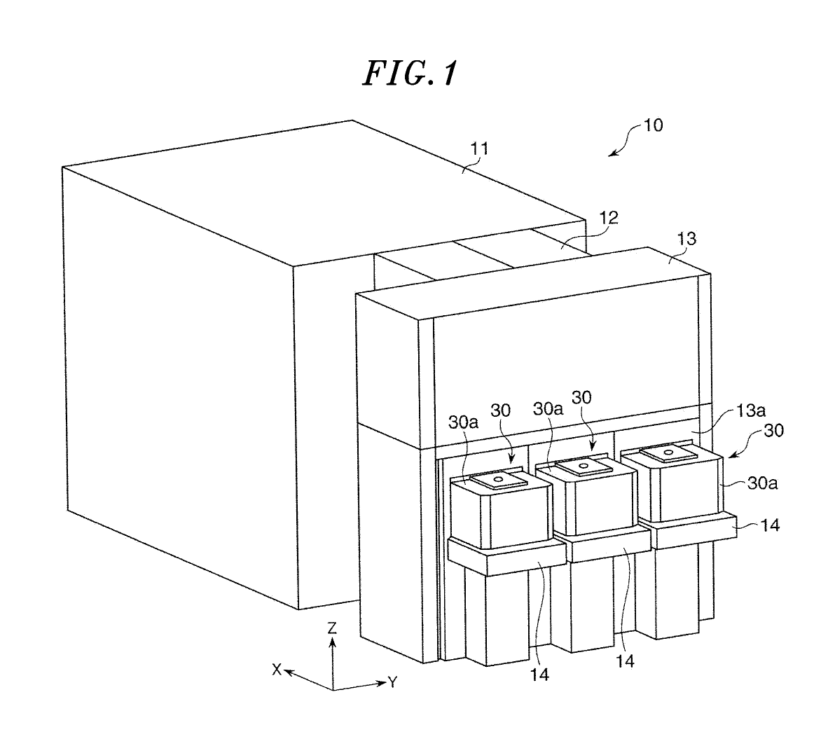

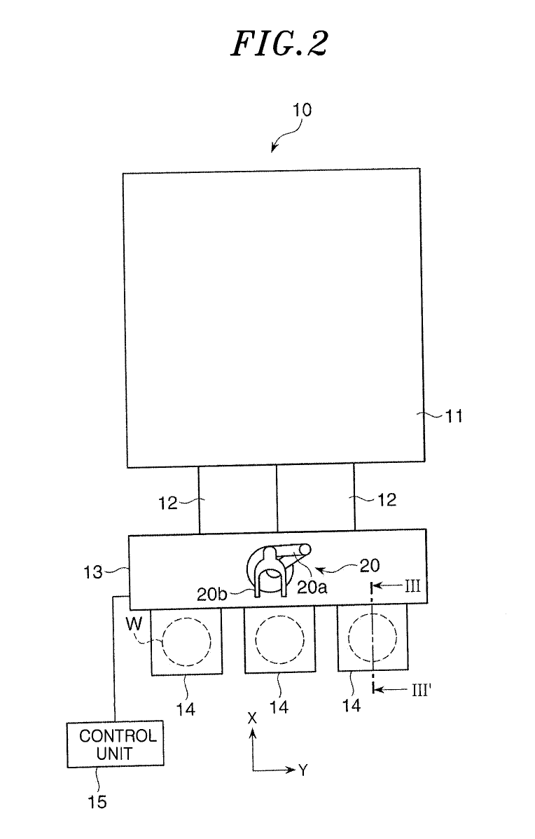

FIG. 1 is a perspective view showing a schematic configuration of a substrate processing apparatus 10 in accordance with an embodiment of the present invention. FIG. 2 is a top view showing the schematic configuration of the substrate processing apparatus 10. As shown in FIGS. 1 and 2, three-dimensional XYZ orthogonal coordinates are set for the substrate processing apparatus 10. The X direction is a horizontal lengthwise direction of the substrate processing apparatus 10. The Y direction is a horizontal width direction of the substrate processing apparatus 10. The Z direction is a vertical direction.

The substrate processing apparatus 10 includes: a wafer processing module 11 for performing a process on a wafer W; a loader module 13 spaced apart from the wafer processing module 11 by a distance to correspond to the wafer processing module 11 in the X direction; a wafer transfer module 12 disposed between the wafer processing module 11 and the loader modules 13; and load ports 14 disposed at a side of the loader module 13 opposite to the wafer transfer module 12 in the X direction.

For example, the wafer processing module 11 has a plurality of process modules (not shown) for performing processes on the wafer W, and a wafer transfer robot (not shown) for transferring the wafer W between the process modules and the wafer transfer module 12. When the wafer processing module 11 needs to perform a process on the wafer W in a vacuum atmosphere, the inside of the wafer processing module 11 is maintained at a predetermined vacuum level, and the atmosphere in the wafer transfer module 12 can be switched between a vacuum and an atmospheric pressure.

The wafer transfer module 12 has a wafer mounting table (mounting table) (not shown) for temporarily mounting thereon the wafer W to be transferred from the loader module 13 to the wafer processing module 11 or the wafer to be returned from the wafer processing module 11 to the loader module 13. A wafer transfer unit disposed in the wafer processing module 11 and a wafer transfer unit 20 disposed in the loader module 13 can access the wafer mounting table disposed in the wafer transfer module 12. The wafer transfer unit 20 will be described later.

The loader module 13 is an atmospheric transfer chamber of a rectangular parallelepiped shape. As shown in FIG. 2, the wafer transfer unit 20 for transferring the wafer W is provided in the loader module 13. The wafer transfer unit 20 has a guide rail (not shown) and a transfer arm 20a of a scalar arm type. The transfer arm 20a is movable along the guide rail, rotatable and extensible/contractible. The transfer arm 20a has at a leading end thereof a fork 20b for mounting and holding the wafer W thereon. The wafer transfer unit 20 transfers the wafer W between the wafer transfer module 12 and a MAC 30 mounted on the load port 14. The MAC 30 will be described later. The wafer transfer unit 20 may be of a fixed type instead of the aforementioned movable type. Further, a transfer arm of a multi-joint long reach type may be used instead of the illustrated transfer arm 20a.

The MAC 30 as a container accommodating therein a plurality of (e.g., 25) wafers W is mounted on each of three load ports 14. Loading and unloading of the wafer W into and from the MAC 30 will be described later in detail. The substrate processing apparatus 10 includes a control unit 15 having a computer. The control unit 15 controls an overall operation of the substrate processing apparatus 10.

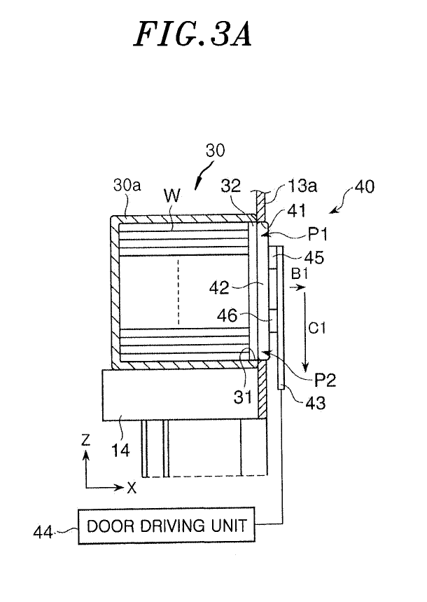

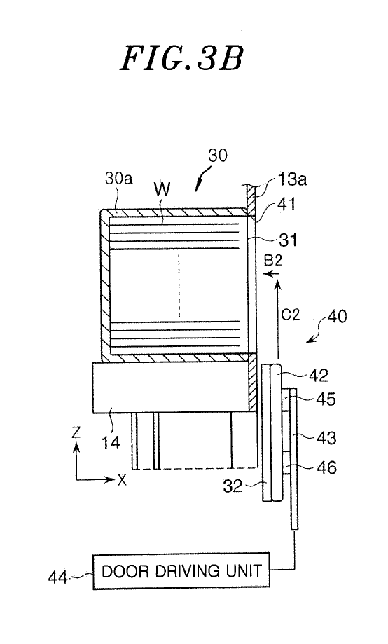

FIGS. 3A and 3B are schematic cross sectional views taken along the line III-III′ shown in FIG. 2. The loader module 13 includes a load port device 40 having a door 42, a column 43, and a door driving unit 44, which will be described later. FIG. 3C is a perspective view showing the schematic structures of the door 42 and the column 43.

As shown in, FIG. 3A, the MAC 30 has an opening 31 through which the wafer W is loaded and unloaded and a lid 32 for closing the opening 31. An opening surface of the opening 31 to which the lid 32 is attached is in parallel to the vertical direction (i.e., surface orthogonal to the X direction (Y-Z surface)).

The MAC 30 is mounted on the load port 14 such that the lid 32 faces the wall 13a of the loader module 13 on the side of the load port 14. When the lid 32 of the MAC 30 is attached to the main body 30a of the MAC 30, the lid 32 is held at the main body 30a as shown in FIG. 3A by a rotatable latch mechanism (not shown) in accordance with SEMI standard for Φ450 mm wafer, for example.

A loading/unloading opening 41 is formed in the wall 13a of the loader module 13 on the side of the load port 14 to correspond to the lid 32 of the MAC 30 mounted on the load port 14. Through the loading/unloading opening 41 the inside of the MAC 30 communicates with the inside of the loader module 13 and the wafer W is loaded into or unloaded from the MAC 30. The loading/unloading opening 41 can be opened/closed by the door 42.

A manipulation mechanism (not shown) is provided at an outer surface of the door 42 (FIMS surface to be described later) to manipulate the latch mechanism holding the lid 32 of the MAC 30. When the MAC 30 is mounted on the load port 14, the lid 32 of the MAC 30 comes into contact with the outer surface of the door 42. Accordingly, the latch mechanism of the lid 32 of the MAC 30 can be released by the manipulation mechanism provided at the door 42. The manipulation mechanism has a function of holding the lid 32 of which latch mechanism has been released. That is, the door 42 releases the latch mechanism of the lid 32 and holds the lid 32 by using the manipulation mechanism.

The door 42 is supported by the column 43 through the leaf springs 45 and 46. The function of the leaf springs 45 and 46 will be described later. The door driving unit 44 moves the door 42 in the arrow B1 direction and then in the arrow C1 direction as shown in FIG. 3A by driving the column 43. Accordingly, the door 42 holding the lid 32 can be moved from a blocking position shown in FIG. 3A to a retracted position shown in FIG. 3B. On the contrary, the door driving unit 44 moves the door 42 in the arrow C2 direction and then in the arrow B2 direction as shown in FIG. 3B. Accordingly, the door 42 holding the lid 32 can be moved from the retracted position in FIG. 3B to the blocking position in FIG. 3A. In the state shown in FIG. 3B, the wafer transfer unit 20 disposed in the loader module 13 can load/unload the wafer W into/from the MAC 30.

When the MAC 30 is mounted on the load port 14, the outer surface of the door 42 blocking the loading/unloading opening 41 formed in the wall 13a of the loader module 13 becomes in parallel to the vertical direction, and the lid 32 of the MAC 30 also becomes in parallel to the vertical direction. Therefore, the latch mechanism installed at the lid 32 can be reliably released by the manipulation mechanism provided at the door 42.

Meanwhile, in order to move the MAC 30 mounted on the load port 14 from the load port 14 to another substrate processing apparatus or the like, the lid 32 needs to be inserted into the opening 31 by moving the door 42 holding the lid 32 from the retracted position in FIG. 3B to the blocking position in FIG. 3A. Further, the lid 32 needs to be reliably attached (fixed) to the main body 30a of the MAC 30.

When the lid 32 is inserted into the opening 31 of the MAC 30, the lid 32 comes into contact with the wafers W accommodated in the MAC 30 and receives a reactive force from the wafers W. The lid 32 and the door 42 are pressed toward the loader module 13 by the reactive force. However, in order to fit the lid 32 into the opening 31, the lid 32 needs to be pressed against the reactive force to a position that allows the lid 32 to be fixed to the main body 30a by the latch mechanism.

Here, a structure in which a door similar to the lid 32 is directly supported by a column similar to the column 43 (without the leaf springs 45 and 46) may be considered. Since the door is supported in a cantilever state, the column may be deformed (displaced) by the reactive force from the wafer W in such a manner that its leading end is moved to the loader module 13 side with its bottom end as a fulcrum point maintained by the door driving unit 44. Accordingly, the door may be inclined such that its upper portion (corresponding to a point P1 in FIG. 3A) is farther away from the MAC 30 compared to its lower portion (corresponding to a point P2 in FIG. 3A).

In other words, the FIMS surface of the door which is in contact with the lid 32 may be inclined with respect to the opening surface of the opening 31 of the MAC 30 (the opening surface being perpendicular to the X direction). If the FIMS surface of the door is inclined, the lid 32 is also inclined with respect to the opening surface of the opening 31.

If the lid 32 is inclined with respect to the opening surface of the opening 31 due to the deformation of the column, the possibility that the latch mechanism is not coupled with the lid 32 and the latch error may occur is increased. Further, when the lid 32 cannot be normally attached to the opening 31, the possibility that the door close error (error that the door cannot be precisely fitted to the opening formed in the wall portion of the loader module) may occur is increased.

To that end, there is employed a method in which the column for supporting the door is made to obtain an increased stiffness enough to be against the reactive force from the wafer, e.g., by making the column thicker. However, in such a method, the weight of the column is increased and, thus, the door driving unit requires a large torque or a mechanical structure for moving the door. This generates problems such as scaling up of the door driving unit, increase of a foot print of the loader module, cost increase and the like.

Therefore, in the present invention, by making the FIMS surface of the door 42 have a degree of freedom with a simple configuration, when the lid 32 is fitted into the opening 31 of the MAC 30, the posture of the door 42 is corrected such that the FIMS surface of the door 42, to which the reactive force from the wafer W is applied through the lid 32, becomes in parallel to the opening surface of the opening 31 (becomes perpendicular to the X direction).

FIG. 3C is a perspective view showing the shape of the leaf springs 45 and 46 and the connection state of the door 42 and the column 43. As shown in FIGS. 3A to 3C, two leaf springs 45 and 46 each having a lengthwise direction in the Y direction are arranged (approximately in parallel) at the door 42 in the vertical direction (Z direction) corresponding to the lengthwise direction of the column 43. The door 42 is supported by the column 43 through the leaf springs 45 and 46.

With such structure, as will be described later, the inclination of the FIMS surface of the door 42 is corrected and the lid 32 is precisely attached to the opening 31 of the MAC 30, which enables the latch mechanism to be normally operated.

In other words, in the door closing operation of fitting the lid 32 into the opening 31 (operation of blocking the loading/unloading opening 41 with the door 42), the door driving unit 44 is driven such that the lid 32 held by the door 42 is inserted into the opening 31, and the door 42 blocks the loading/unloading opening 41 of the wall 13a. At this time, the lid 32 comes into contact with the wafers W accommodated in the MAC 30 and the reactive force is applied from the wafers W to the lid 32. Then, the column 43 may be deformed such that its leading end side is moved to the loader module 13 side with its bottom portion acting as a fulcrum point. However, in accordance with the embodiment of the present invention, the leaf springs 45 and 46 are deformed to absorb the reactive force from the wafer W. As a consequence, the FIMS surface of the door 42 can be maintained in parallel to the opening surface of the opening 31 of the MAC 30.

In this manner, the inclination of the door 42 is prevented, and the inclination of the lid 32 held by the door 42 is also prevented. Therefore, the lid 32 can be reliably pressed to the opening 31 against the reactive force from the wafers W. Accordingly, when the manipulation mechanism of the door 42 is driven, the latch mechanism of the lid 32 can be coupled to the main body 30a of the MAC 30. As a result, the latch error and the door close error can be prevented.

The leaf springs 45 and 46 may have the same spring constant as long as the FIMS surface of the door 42 is corrected to be in parallel to the vertical direction when the lid 32 is attached to the opening 31 of the MAC 30 and the reactive force is applied from the wafers W accommodated in the MAC 30 to the lid 32. The size (shape) of the leaf springs 45 and 46 is not limited. Meanwhile, in consideration of the status of the deformation of the column 43 by the reactive force applied from the wafers W to the lid 32, the leaf spring 45 may have a large spring constant than that of the leaf spring 46. In other words, since the leaf spring 46 disposed at the lower portion absorbs the reactive force from the wafers W to be contracted by urging the deformed column 43 toward the MAC 30 side (in the arrow B2 direction in FIG. 3B), the lid 32 can be pressed to the opening 31 while maintaining the FIMS surface of the door 42 in perpendicular to the X direction.

Although two leaf springs 45 and 46 are provided between the door 42 and the column 43 in this example, three or more leaf springs may be arranged in the Z direction. Accordingly, the inclination of the FIMS surface of the door can be more precisely corrected. In case that the inclination of the FIMS surface of the door 42 can be corrected by a single leaf spring, the single leaf spring may be disposed between the door 42 and the column 43.

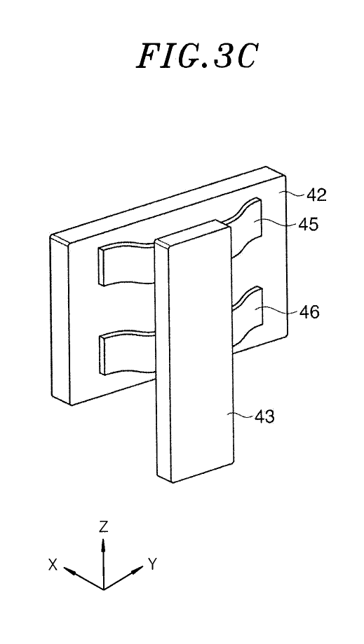

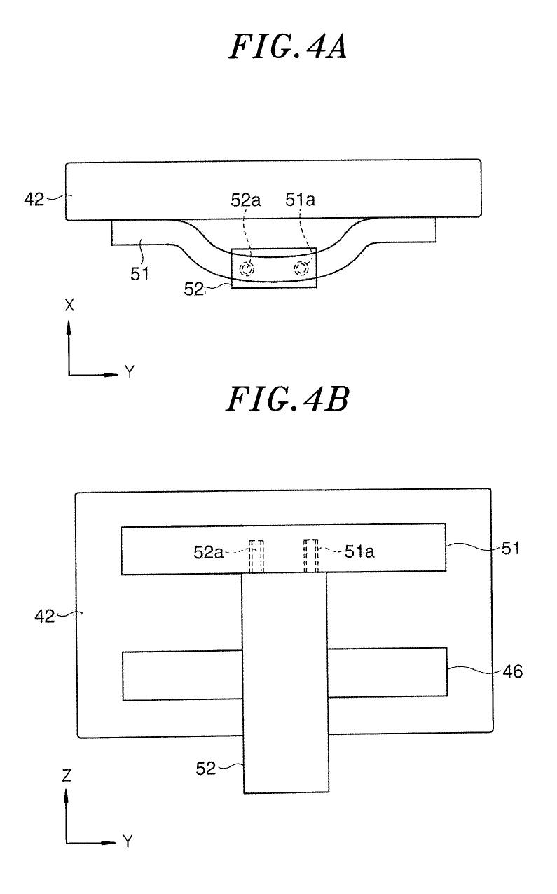

Hereinafter, a modification of the example in which the door 42 is supported by the column 43 will be described. FIGS. 4A and 4B are a top view and a rear view showing another type of supporting the door 42. The door 42 is supported by a column 52 through a leaf spring 51 and a leaf spring 46 (equivalent to the leaf spring 46 shown in FIGS. 3A to 3C).

Holes 51a are formed in the bottom surface of the leaf spring 51 (lower end surface in the Z direction) and pins (protrusions) 52a provided at a top surface of the column 52 are inserted in the holes 51a. The leaf spring 51 is supported by the column 52 in a state where the pins 52a are inserted in the respective holes 51a. A small gap (clearance) is formed between an inner surface of each hole 51a and an outer surface of each pin 52a inserted in the corresponding hole 51a. The gap absorbs the reactive force applied from the wafers W in the MAC 30 to the lid 32 at the time of fitting the lid 32 held by the door 42 into the opening 31 of the MAC 30, thereby allowing the inclination of the door 42 to be corrected and the FIMS surface of the door 42 to be maintained in parallel to the vertical direction.

Therefore, if the clearance can absorb the deformation of the column 52 by the reactive force applied from the wafers W accommodated in the MAC 30 to the lid 32, a plate having no elasticity may be used instead of the leaf spring 51.

Although the above embodiment has been described in which the substrate processing apparatus 10 has the load port device 40, the present invention is not limited thereto. For example, in the above embodiment, the inclination of the FIMS surface of the door 42 is corrected by absorbing the reactive force applied from the wafers W to the lid 32 by using two leaf springs 45 and 46 arranged in parallel. However, the inclination of the FIMS surface of the door 42 may be corrected by using, instated of the leaf springs 45 and 46, an elastic body (including, e.g., a plate-shaped frame and a coil spring) having the same function as that of the leaf springs 45 and 46. Further, two parallel leaf springs 45 and 46 may be replaced with an X-shaped single leaf spring.

In the above embodiment, the substrate processing apparatus 10 includes the wafer processing module 11, the wafer transfer module 12, the loader module 13 and the load ports 14. However, there may be employed a configuration in which the wafer W is loaded into and unloaded from the process modules of the wafer processing module 11 by the wafer transfer unit 20 disposed in the loader module 13 without providing the wafer transfer module 12. Further, in the above embodiment, the MAC 30 is used as a container accommodating therein wafers W. However, the container may be a FOUP (Front-Opening Unified Pod) accommodating therein wafers W of Φ450 mm. The present invention may also be applied to a load port device for attaching/detaching a lid of a FOUP accommodating therein wafers W of Φ300 mm.

While the invention has been shown and described with respect to the embodiments, it will be understood by those skilled in the art that various changes and modifications may be made without departing from the scope of the invention as defined in the following claims.

What is claimed is:

1. A load port device for allowing transfer of a semiconductor wafer between an inside of a substrate processing apparatus for processing the semiconductor wafer and an inside of a container accommodating therein semiconductor wafers by opening a lid of the container and an opening of the substrate processing apparatus when the container is disposed outside the substrate processing apparatus such that the lid faces the opening, the load port device comprising:
a door for opening and closing the opening from the inside of the substrate processing apparatus, the door being configured to attach and detach the lid of the container to and from a main body of the container while holding the lid;
a door driving unit for driving the door to open and close the opening; and
an elastic body disposed on a first surface of the door, which is opposite to a second surface in contact with the lid when the lid is held by the door, the elastic body being configured to correct inclination of the second surface of the door with respect to an opening surface of the container to which the lid is to be attached when the lid held by the door is attached to the main body of the container by the door driving unit and receives a reactive force from the semiconductor wafer accommodated in the container.

2. The load port device of claim 1, further comprising:
a column attached to the door driving unit and configured to support the door in a cantilever state through the elastic body and move the door according to said driving of the door driving unit,
wherein the elastic body includes at least two leaf springs spaced apart from each other in a lengthwise direction of the column.

3. The load port device of claim 2, wherein the leaf springs include a first leaf spring disposed at a leading end side of the column and a second leaf spring disposed at the door driving unit side of the column, the first leaf spring having a spring constant greater than a spring constant of the second leaf spring.

4. The load port device of claim 2, wherein the column includes a protrusion at a top surface thereof,
wherein an uppermost one of the leaf springs includes a hole formed in a bottom surface thereof, and
wherein the protrusion of the column is inserted through the hole such that a gap is formed between an outer surface of the protrusion and an inner surface of the hole.

5. The load port device of claim 3, wherein the column includes a protrusion at a top surface thereof,
wherein the first leaf spring includes a hole formed in a bottom surface thereof, and
wherein the protrusion of the column is inserted through the hole such that a gap is formed between an outer surface of the protrusion and an inner surface of the hole.

6. A substrate processing apparatus comprising:
a substrate processing unit configured to perform a process on a semiconductor wafer;
a load port configured to mount thereon a container accommodating semiconductor wafers to be processed by the substrate processing unit and/or semiconductor wafers processed by the substrate processing unit; and
a loader module including an opening formed to face the container mounted on the load port, the loader module providing therein a wafer transfer unit for loading and unloading the semiconductor wafer into and from the container through the opening,
wherein the loader module further includes a load port device configured to open a lid of the container and the opening when the container is mounted on the load port, and
wherein the load port device includes:
a door for opening and closing the opening from the inside of the loader module, the door being configured to attach and detach the lid of the container to and from a main body of the container while holding the lid;
a door driving unit for driving the door to open and close the opening; and
an elastic body disposed on a first surface of the door which is opposite to a second surface in contact with the lid when the lid is held by the door, the elastic body being configured to correct inclination of the second surface of the door with respect to an opening surface of the container to which the lid is attached, when the lid held by the door is attached to the main body of the container by the door driving unit and receives a reactive force from the semiconductor wafer accommodated in the container.
